(19) United States
(12) Patent Application Publication
(10) Pub. No.: US 2025/0096053 A1
(43) Pub. Date: Mar. 20, 2025

(54) MICROELECTRONIC ASSEMBLIES HAVING A BRIDGE DIE OVER A GLASS PATCH

(71) Applicant: Intel Corporation, Santa Clara, CA (US)

(72) Inventors: Jeremy Ecton, Gilbert, AZ (US); Brandon C. Marin, Gilbert, AZ (US); Bohan Shan, Chandler, AZ (US); Tarek A. Ibrahim, Mesa, AZ (US); Srinivas V. Pietambaram, Chandler, AZ (US); Gang Duan, Chandler, AZ (US); Benjamin T. Duong, Phoenix, AZ (US); Suddhasattwa Nad, Chandler, AZ (US)

(73) Assignee: Intel Corporation, Santa Clara, CA (US)

(21) Appl. No.: 18/470,645

(22) Filed: Sep. 20, 2023

(51) Int. Cl. H01L 23/15; H01L 23/498; H01L 23/522; H01L 23/538; H01L 25/065

(52) U.S. Cl. CPC H01L 23/15; H01L 23/49816; H01L 23/49827; H01L 23/5226; H01L 23/5385; H01L 25/0652

(57) ABSTRACT

A microelectronic assembly includes an embedded bridge die and a glass structure, such as glass patch, under the bridge die. The bridge die and the glass structure are embedded in a substrate. The assembly may further include two or more dies arranged over the substrate and coupled to the bridge die. The glass structure may include through-glass vias, and vias in the substrate below the glass structure are self-aligned to the through-glass vias. The glass structure may include an embedded passive device, such as an embedded inductor or capacitor.

### BACKGROUND

Integrated circuit (IC) devices (e.g., dies) can be coupled together in a multi-die IC package to integrate features or functionality and to facilitate connections to other components, such as package substrates. IC packages may include an embedded multi-die interconnect bridge (EMIB) for coupling two or more IC dies.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of an example microelectronic assembly, in accordance with various embodiments.

FIG. 2 is a flow diagram of an example process for manufacturing a microelectronic assembly, in accordance with various embodiments.

FIGS. 3A-3M are side, cross-sectional views of various stages in an example process for manufacturing the microelectronic assembly of FIG. 1, in accordance with various embodiments.

FIG. 4 is an example zoomed view of a portion of FIG. 3M, in accordance with various embodiments.

FIG. 5 is an example zoomed view of portion of FIG. 4, in accordance with various embodiments.

FIGS. 6A-6F are side, cross-sectional views of various stages in another example process for manufacturing a microelectronic assembly, in accordance with various embodiments.

FIGS. 7A-7E illustrate several example implementations of glass patches including passive devices, in accordance with various embodiments.

FIG. 8 is a top view of a wafer and dies that may be included in a microelectronic assembly, in accordance with any of the embodiments disclosed herein.

FIG. 9 is a cross-sectional side view of an IC device that may be included in a microelectronic assembly, in accordance with any of the embodiments disclosed herein.

FIG. 10 is a cross-sectional side view of an IC device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Communicating large numbers of signals between two or more dies in a multi-die IC package is challenging due to the increasingly small size of such dies and increased use of stacking dies. As transistor density increases with each new silicon node, yielding large, monolithic dies has become increasingly difficult, leading to an industry push toward die disaggregation. Multi-die IC packaging typically requires increased die segregation, additional power delivery requirements, and stricter routing and alignment tolerances throughout the package. The greater number of embedded dies and smaller size of embedded dies (i.e., bridge dies, passives, etc.) vastly increases manufacturing complexity as well as routing complexity as power signals must be routed around embedded dies. Various ones of the embodiments disclosed herein may help reduce the cost and complexity associated with assembling multi-die IC packages relative to conventional approaches by incorporating double-sided embedded dies with through-silicon vias (TSVs) that enable power signals to be routed through the embedded dies.

To produce packages with embedded dies, the embedded dies may be placed into a cavity in a substrate and bonded to the substrate using solder bonds. For example, solder bonds may couple the TSVs in the embedded die to power connections in the underlying substrate. When solder bonds are used, an underfill dielectric material is deposited below the embedded die, in the gaps between the solder bumps. However, it can be challenging to flow the dielectric underneath the embedded die in the cavity. Variation in solder bump height and/or incomplete underfill can lead to structural inconsistencies, e.g., the embedded die being slightly tilted, rather than level. If the embedded die is not level, it can be challenging to properly align and mount dies over the embedded die. Furthermore, solder bonds have relatively high resistance compared to other bonding methods, such as direct bonding or hybrid bonding.

As described herein, a glass patch is included in a microelectronic assembly, below the embedded die. The glass patch may include through-glass vias (TGVs) to couple power connections in the substrate to power connections in the embedded die. The glass patch has openings formed therein for forming the TGVs. The glass patch may be bonded to the substrate, and a self-aligned etch may etch vias in an upper portion of the substrate to metal lines already formed in the substrate. The embedded die may be hybrid bonded to the glass patch, rather than using solder bonds. The glass patch provides lower-resistance connections to power delivery in the substrate. Furthermore, the glass patch provides increased stability for the embedded die and the dies mounted overtop of the embedded die, reducing alignment errors.

In some embodiments, in addition to the TGVs, one or more passive components may be embedded in the glass patch. The TGVs may be power vias that provide power to one or more dies in the multi-die package. Passive devices such as inductors or transformers can be used in power delivery applications, e.g., to change a voltage level, or to provide power at multiple different voltage levels. As another example, resistors and capacitors may be incorporated in the package to reduce electromagnetic interference (EMI) and/or suppress electrostatic discharge (ESD).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features. It is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.” Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

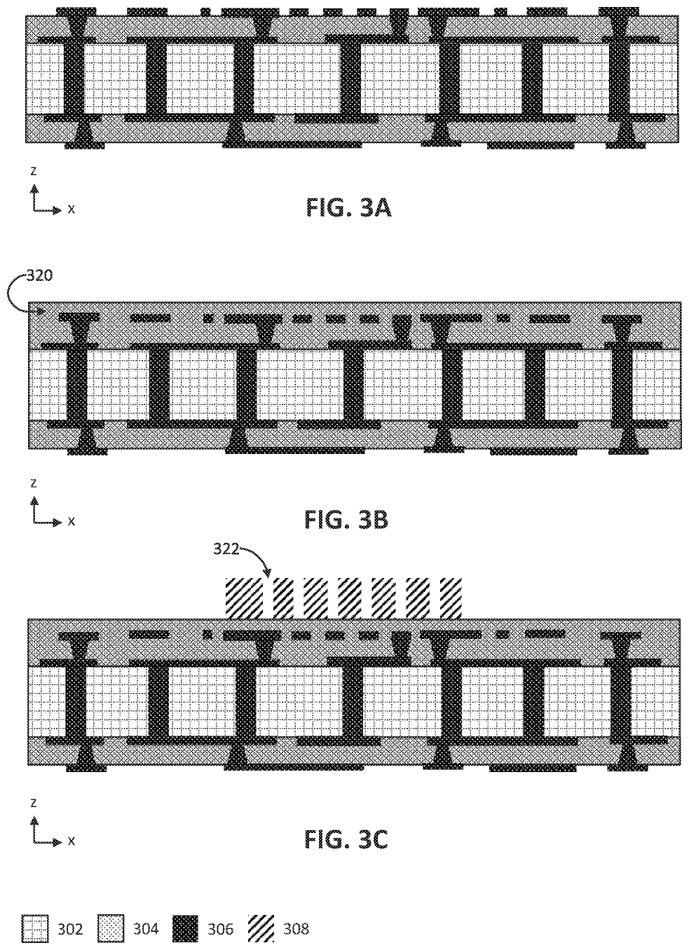

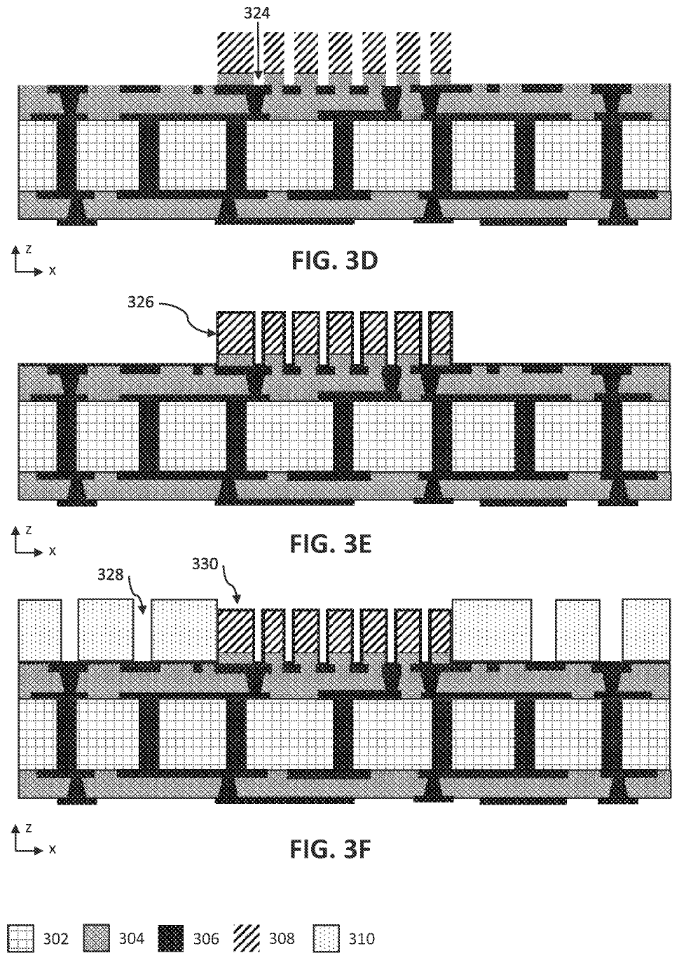

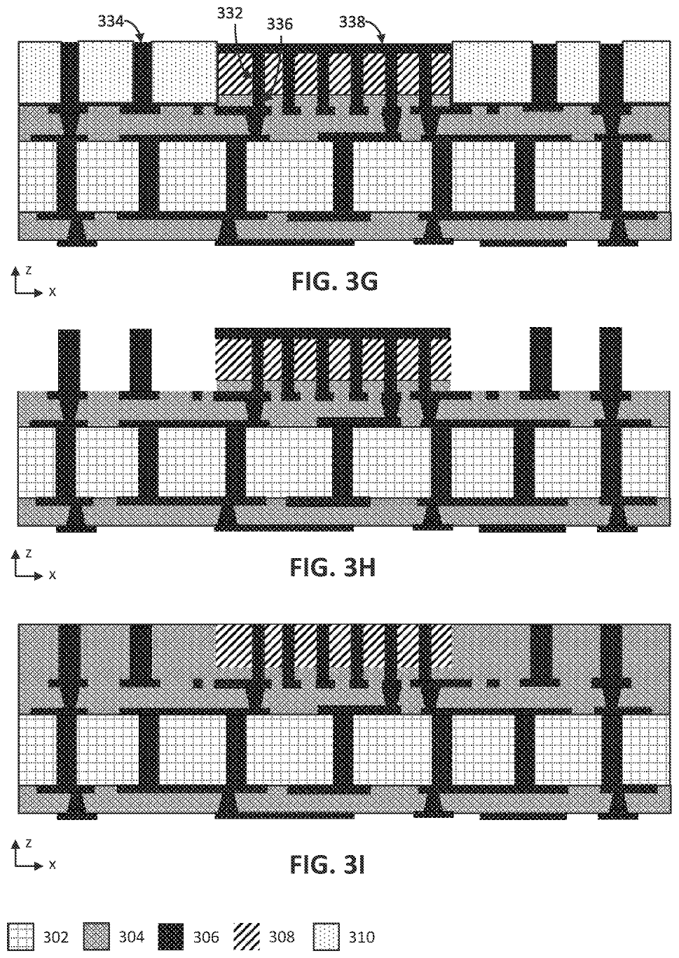

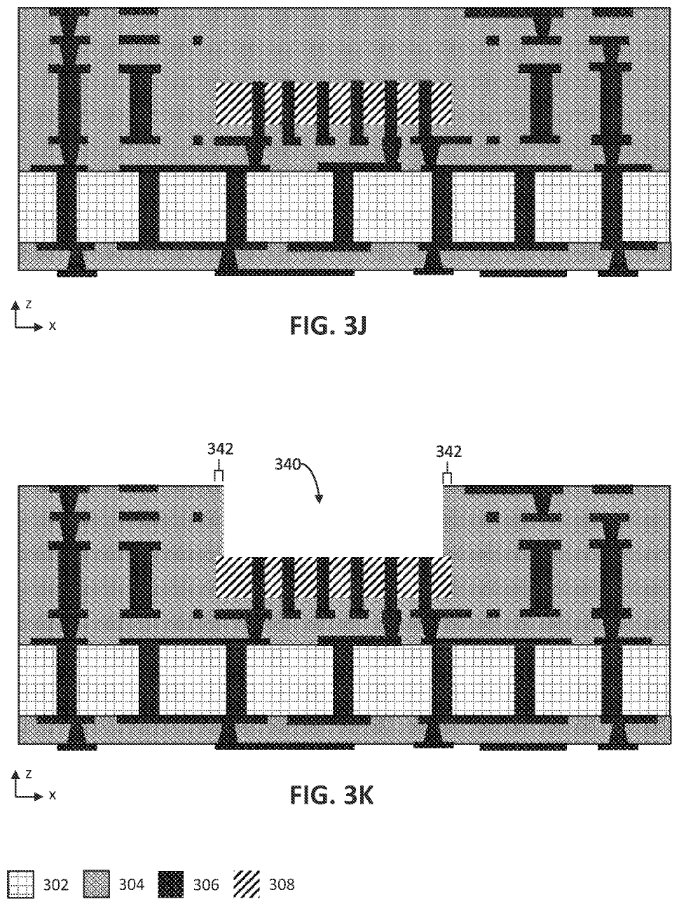

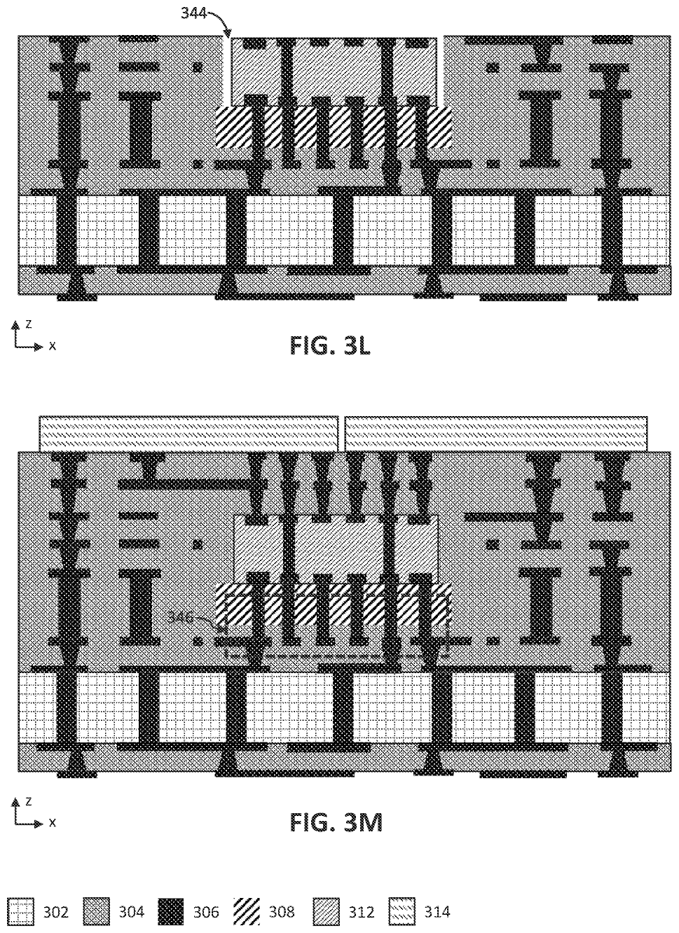

When used to describe a range of dimensions, the phrase “between X and Y” represents a range that includes X and Y. For convenience, the phrase “FIG. 3” may be used to refer to the collection of drawings of FIGS. 3A-3M, the phrase “FIG. 5” may be used to refer to the collection of drawings of FIGS. 5A-5F, etc. Although certain elements may be referred to in the singular herein, such elements may include multiple sub-elements. For example, “an insulating material” may include one or more insulating materials.

### Example Assembly with Glass Patch Under Embedded Bridge Die

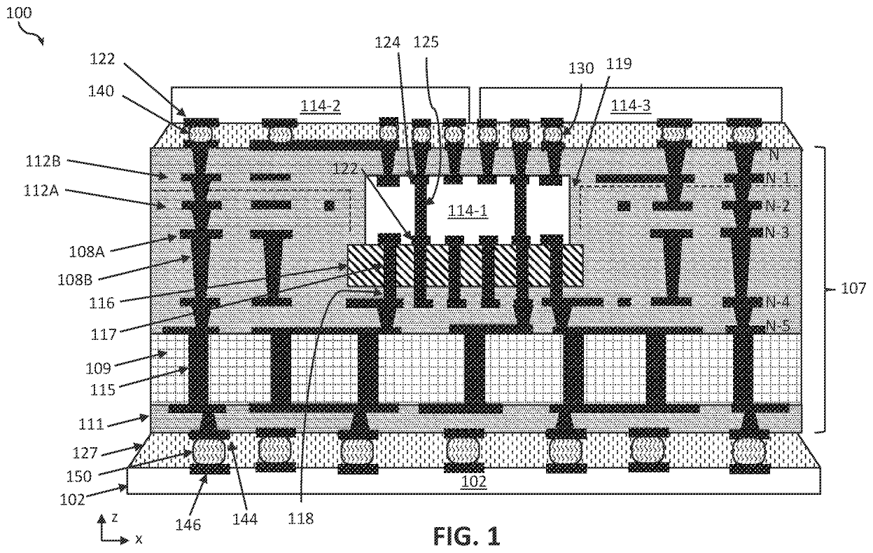

FIG. 1 is a side, cross-sectional view of an example microelectronic assembly, in accordance with various embodiments. The microelectronic assembly 100 may include a substrate 107 with a double-sided bridge die 114-1 that is formed within a cavity 119 in the substrate 107, as illustrated in the process steps shown in FIGS. 3 and 5. The die 114-1 is over a glass structure 116 having TGVs 117 extending through the glass structure 116. The die 114-1 is electrically coupled, by the TGVs 117 of the glass structure 116, to a conductive trace 108A in a metal layer of the substrate 107 that is beneath a bottom of the cavity 119. The substrate 107 may include a dielectric material 112 (e.g., a first dielectric material layer 112A and a second dielectric material layer 112B, as shown) and a conductive material 108 (e.g., lines/traces/pads/contacts 108A and vias 108B, as shown), with the conductive material 108 arranged in the dielectric material 112 to provide conductive pathways through the substrate 107. The die 114-1 may be surrounded by a dielectric material 112 of the substrate 107.

The die 114-1 may include a bottom surface with first conductive contacts 122, an opposing top surface with second conductive contacts 124, and TSVs 125 coupling respective first and second conductive contacts 122, 124. In some embodiments, a pitch of the first conductive contacts 122 on the first die 114-1 maybe between 25 microns and 250 microns. As used herein, pitch is measured center-to-center (e.g., from a center of a conductive contact to a center of an adjacent conductive contact). In some embodiments, a pitch of the second conductive contacts 124 on the first die 114-1 maybe between 25 microns and 100 microns.

The dies 114-2, 114-3 may include a set of conductive contacts 122 on the bottom surface of the die (e.g., the surface facing towards an upper surface of the substrate 107). The dies 114-1, 114-2, and 114-3 may include other conductive pathways (e.g., including lines and vias) and/or to other circuitry (not shown) coupled to the respective conductive contacts (e.g., conductive contacts 122, 124) on the surfaces of the dies 114. As used herein, the terms “die,” “microelectronic component,” and similar variations may be used interchangeably. As used herein, the terms “interconnect component,” “bridge die,” and similar variations may be used interchangeably. The bridge die 114-1 may be electrically coupled to dies 114-2, 114-3 by die-to-die (DTD) interconnects 130. The DTD interconnects 130 are over the upper surface of the substrate 107. In particular, conductive contacts 124 on a top surface of the die 114-1 may be coupled to conductive contacts 122 on a bottom surface of dies 114-2, 114-3 by conductive vias 108B through the dielectric material 112B and DTD interconnects 130.

As used herein, a “conductive contact” may refer to a portion of conductive material (e.g., metal) serving as an electrical interface between different components (e.g., part of a conductive interconnect); conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

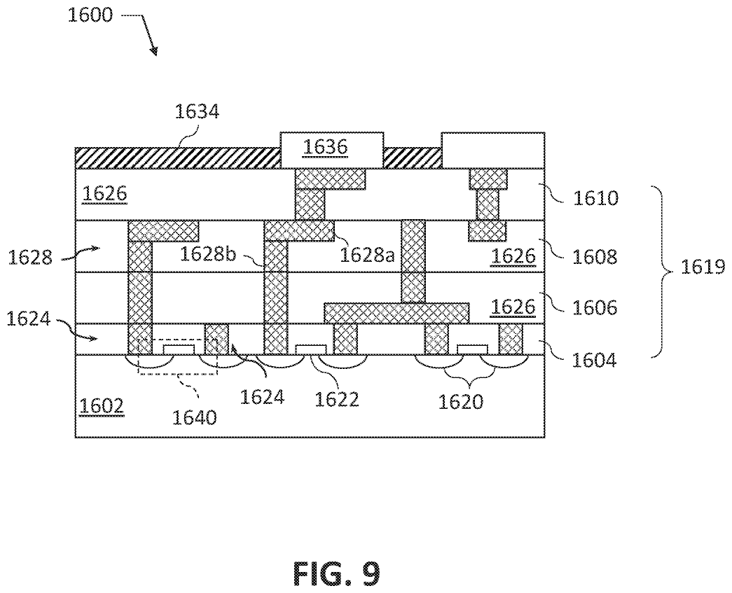

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 9. The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked).

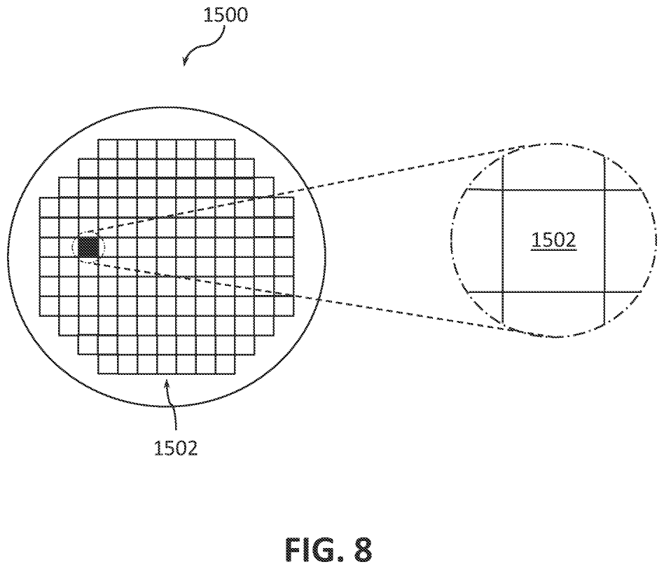

In some embodiments, the die 114 may include conductive pathways to route power, ground, and/or signals to/from other dies 114 included in the microelectronic assembly 100. For example, the die 114-1 may include TSVs 125, including a conductive material via, such as a metal via, isolated from the surrounding silicon or other semiconductor material by a barrier oxide), or other conductive pathways through which power, ground, and/or signals may be transmitted between a package substrate 102 and one or more dies 114 “on top” of the die 114-1 (e.g., in the embodiment of FIG. 1, the dies 114-2 and/or 114-3). In some embodiments, the die 114-1 may not route power and/or ground to the dies 114-2 and 114-3; instead, the dies 114-2, 114-3 may couple directly to power and/or ground lines in the package substrate 102 by substrate-to-package substrate (STPS) interconnects 150, conductive pathways 108 in the substrate 107, and die-to-substrate (DTS) interconnects 140. In some embodiments, the die 114-1 may be thicker than the dies 114-2, 114-3. In some embodiments, the die 114-1 may be a memory device (e.g., as described below with reference to the die 1502 of FIG. 8), or a high frequency serializer and deserializer (SerDes), such as a Peripheral Component Interconnect (PCI) express. In some embodiments, the die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor.

The dielectric material 112 of the substrate 107 may be formed in layers (e.g., at least a first dielectric material layer 112A and a second dielectric material layer 112B). In some embodiments, the dielectric material 112 may include an organic material, such as an organic buildup film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 107 may include layers of dielectric material 112/conductive material 108, with lines/traces/pads/contacts (e.g., 108A) of conductive material 108 in one layer electrically coupled to lines/traces/pads/contacts (e.g., 108A) of conductive material 108 in an adjacent layer by vias (e.g., 108B) of the conductive material 108 extending through the dielectric material 112. Conductive elements 108A may be referred to herein as “conductive lines,” “conductive traces,” “conductive pads,” or “conductive contacts.” A substrate 107 including such layers may be formed using a printed circuit board (PCB) fabrication technique, for example.

An individual layer of dielectric material 112 (e.g., a first dielectric material layer 112A) may include a cavity 119 and the bridge die 114-1 may be at least partially nested in the cavity 119. The bridge die 114-1 may be surrounded by (e.g., embedded in) a next individual layer of dielectric material 112 (e.g., a second dielectric material layer 112B. In some embodiments, a cavity 119 is tapered, narrowing towards a bottom surface of the cavity 119. A cavity 119 may be indicated by a seam between the dielectric material layer 112A and the dielectric material layer 112B. As shown in FIG. 1, in cases where the bridge die 114-1 is partially nested in a cavity 119, a top surface of the bridge die 114-1 may extend above a top surface of dielectric material layer 112A. In cases where the bridge die 114-1 is fully nested in a cavity 119, a top surface of the bridge die 114-1 is planar with a top surface of dielectric material layer 112A.

The bridge die 114-1 is over a glass structure 116, also referred to as a glass patch. The glass structure 116 has an upper face that is coupled to the bridge die 114-1, and a lower face that is coupled to the substrate 107. The glass structure 116 is a layer of glass having a shape similar to the bridge die 114-1. For example, if the bridge die 114-1 has a length extending in the x-direction in the coordinate system shown, the glass structure 116 may have a length that is equal to or greater than (e.g., around 5% greater than, 10% greater than, or 20% greater than) the length of the bridge die 114-1. Similarly, if the bridge die 114-1 has a width extending in the y-direction in the coordinate system shown (e.g., into the drawing page), the glass structure 116 may have a width that is equal to or greater than (e.g., around 5% greater than, 10% greater than, or 20% greater than) the width of the bridge die 114-1. The glass structure 116 may have a height extending in the z-direction in the coordinate system shown that is in the range of 20-500 microns or a range therein, e.g., between 20 and 50 microns, or between 50 and 200 microns.

The glass structure 116 includes any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass structure 116 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass structure 116 may be an amorphous solid glass layer. In some embodiments, the glass structure 116 may include silicon and oxygen, as well as any one or more of aluminum, boron, magnesium, calcium, barium, tin, sodium, potassium, strontium, phosphorus, zirconium, lithium, titanium, and zinc. In some embodiments, the glass structure 116 may include a material, e.g., any of the materials described above, with a weight percentage of silicon being at least about 0.5%, e.g., between about 0.5% and 50%, between about 1% and 48%, or at least about 23%. For example, if the glass structure 116 is fused silica, the weight percentage of silicon may be about 47%. In some embodiments, the glass structure 116 may include at least 23% silicon and/or at least 26% oxygen by weight, and, in some further embodiments, the glass structure 116 may further include at least 5% aluminum by weight. In some embodiments, the glass structure 116 may include any of the materials described above and may further include one or more additives such as Al2O3, B2O3, MgO, CaO, SrO, BaO, SnO2, Na2O, K2O, SrO, P2O3, ZrO2, Li2O, Ti, and Zn. In some embodiments, the glass structure 116 may be a layer of glass that does not include an organic adhesive or an organic material. In some embodiments, a cross-section of the glass structure 116 in an x-z plane, a y-z plane, and/or an x-y plane of the coordinate system may be substantially rectangular.

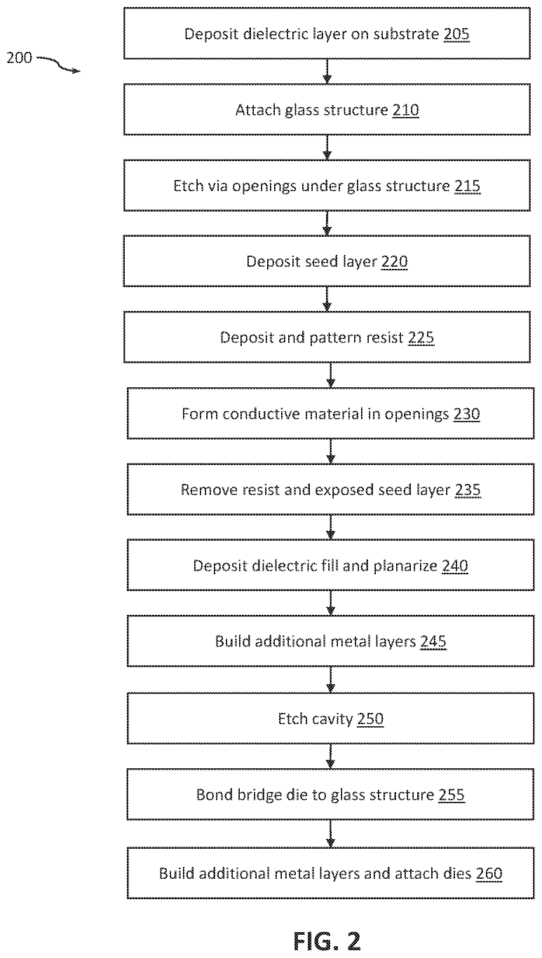

TGVs 117 extend through the glass structure 116. The TGVs 117 may include a conductive material, such as copper or another metal. The glass structure 116 may include TGV openings that are filled with a conductive material after the glass structure 116 is attached to the substrate 107. For example, openings for forming the TGVs 117 may be formed using a laser process, e.g., laser induced deep etching (LIDE), or a lithographic process, e.g., photolithography. Respective first conductive contacts 122 on the bottom surface of the bridge die 114-1 in the cavity 119 may be electrically coupled to respective TGVs 117 at the upper face of the glass structure 116. At the opposite face of the glass structure 116, the TGVs 117 are coupled to vias 118 through the dielectric material 112 below the glass structure 116. In the example of FIG. 1, the vias 118 are coupled to conductive traces in the N-4 metal layer. The vias 118 may be formed using a self-aligned etching process, where the via openings in the glass structure 116 are used to pattern the dielectric material 112 below the glass structure 116 and form openings for the vias 118. This is described further in relation to FIGS. 2-5.

In addition to the TGVs 117, in some embodiments, the glass structure 116 includes one or more passive devices. A passive device is a component that does not require an external power source to perform its intended function within an electronic circuit. Passive devices primarily manipulate electrical signals without adding or generating energy. The glass structure 116 may include passive components such as resistors, capacitors, inductors, filters, or transformers.

The substrate 107 may include N layers of conductive material 108, where N is an integer greater than or equal to one; in the accompanying drawings, the layers are labeled in descending order from the upper surface of the substrate 107 (e.g., layer N, layer N-1, layer N-2, etc.). In particular, as shown in FIG. 1, a substrate 107 may include six metal layers (e.g., N, N-1, N-2, N-3, N-4, and N-5). The N metal layer may include conductive contacts 108A at a top surface of the substrate 107 that are coupled to conductive contacts 122 at bottom surfaces of the die 114-2, 114-3 by DTS interconnects 140. The N-3 metal layer may include conductive traces 108A having a top surface, an opposing bottom surface, and lateral surfaces extending between the top and bottom surfaces of the conductive traces 108A.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers are shown in the substrate 107 (e.g., six layers), these layers may represent only a portion of the substrate 107, for example, fewer layers may be present, or further layers may be present (e.g., layers N-6, N-7, etc.). As shown in FIG. 1, the substrate 107 may further include a core 109 with through core vias 115 and one or more further layers 111 may be present below the core 109. The substrate 107 (e.g., the lower layer(s) 111) may be coupled to a package substrate 102 by interconnects 150. In some embodiments, a substrate 107 may not include a core 109 and/or further layers 111. The core 109 may be formed of any suitable material, including glass, a fiber-reinforced epoxy, an organic dielectric material, such as an epoxy, or a phenolic resin or polyimide resin reinforced with glass, aramid, or nylon.

The substrate 107 (e.g., further layers 111) may be coupled to a package substrate 102 by STPS interconnects 150. In particular, the top surface of the package substrate 102 may include a set of conductive contacts 146. Conductive contacts 144 on the bottom surface of the substrate 107 may be electrically and mechanically coupled to the conductive contacts 146 on the top surface of the package substrate 102 by the STPS interconnects 150. The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), BT resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

In some embodiments, the package substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process. In some embodiments, additional dies may be disposed on the top surface of the dies 114-2, 114-3. In some embodiments, additional components may be disposed on the top surface of the dies 114-2, 114-3. Additional passive components, such as surface-mount resistors, capacitors, and/or inductors, may be disposed on the top surface or the bottom surface of the package substrate 102, or embedded in the package substrate 102.

The microelectronic assembly 100 of FIG. 1 may also include an underfill material 127. In some embodiments, the underfill material 127 may extend between the substrate 107 and the package substrate 102 around the associated STPS interconnects 150. In some embodiments, the underfill material 127 may extend between different ones of the top level dies 114-2, 114-3 and the top surface of the substrate 107 around the associated DTS interconnects 140 and between the bridge die 114-1 and the top level dies 114-2, 114-3 around the DTD interconnects 130. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the multi-layer die subassembly 104 to the package substrate 102 when forming the STPS interconnects 150, and then polymerizes and encapsulates the STPS interconnects 150. The underfill material 127 may be selected to have a coefficient of thermal expansion (CTE) that may mitigate or minimize the stress between the substrate 107 and the package substrate 102 arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114 and/or dielectric material 112 of the substrate 107.

The STPS interconnects 150 disclosed herein may take any suitable form. In some embodiments, a set of STPS interconnects 150 may include solder (e.g., solder bumps or balls that are subject to a thermal reflow to form the STPS interconnects 150), for example, as shown in FIG. 1, the STPS interconnects 150 may include solder between a conductive contacts 144 on a bottom surface of the substrate 107 and a conductive contact 146 on a top surface of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. The DTD interconnects 130 may have a finer pitch than the STPS interconnects 150 in a microelectronic assembly. In some embodiments, the dies 114 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material, such as any of the materials discussed above. In some embodiments, the DTD interconnects 130 may be used as data transfer lanes, while the STPS interconnects 150 may be used for power and ground lines, among others. In some embodiments, some or all of the DTD interconnects 130 in a microelectronic assembly 100 may be metal-to-metal interconnects (e.g., copper-to-copper interconnects, or plated interconnects). In such embodiments, the DTD interconnect 130 may be bonded together (e.g., under elevated pressure and/or temperature) without the use of intervening solder or an anisotropic conductive material. Any of the conductive contacts disclosed herein (e.g., the conductive contacts 122, 124, 144, and/or 146) may include bond pads, solder bumps, conductive posts, or any other suitable conductive contact, for example. In some embodiments, some or all of the DTD interconnects 130 and/or the DTS interconnects 140 in a microelectronic assembly 100 may be solder interconnects that include a solder with a higher melting point than a solder included in some or all of the STPS interconnects 150. For example, when the DTD interconnects 130 and the DTS interconnects 140 in a microelectronic assembly 100 are formed before the STPS interconnects 150 are formed, solder-based DTD interconnects 130 and DTS interconnects 140 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 due to the greater similarity of materials in the different dies 114 on either side of a set of DTD interconnects 130 than between the substrate 107 and the top level dies 114-2, 114-3 on either side of a set of DTS interconnects 140, and between the substrate 107 and the package substrate 102 on either side of a set of STPS interconnects 150. In particular, the differences in the material composition of a substrate 107 and a die 114 or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies 114 on either side of the DTD interconnects. In some embodiments, the DTS interconnects 140 disclosed herein may have a pitch between 25 microns and 250 microns. In some embodiments, the STPS interconnects 150 disclosed herein may have a pitch between 55 microns and 1000 microns, while the DTD interconnects 130 disclosed herein may have a pitch between 25 microns and 100 microns.

The microelectronic assembly 100 of FIG. 1 may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102, but may instead be coupled to a circuit board, such as a PCB.

Although FIG. 1 depicts a microelectronic assembly 100 having a substrate with a particular number of dies 114 and conductive pathways 108 coupled to other dies 114, this number and arrangement are simply illustrative, and a microelectronic assembly 100 may include any desired number and arrangement of dies 114. Although FIG. 1 shows the die 114-1 as a double-sided die and the dies 114-2, 114-3 as single-sided dies, the dies 114-2, 114-3 may be double-sided dies and the dies 114 may be a single-pitch die or a mixed-pitch die. In some embodiments, additional components may be disposed on the top surface of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the microelectronic assembly 100, but a number of these elements may not be present in a microelectronic assembly 100. For example, in various embodiments, the core 109, the further layers 111, the underfill material 127, and the package substrate 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

### Example Process for Forming Assembly with Glass Patch Under Embedded Bridge

Any suitable techniques may be used to manufacture the microelectronic assembly 100 disclosed herein. FIG. 2 illustrates one example process 200 that may be used to manufacture the microelectronic assembly 100. FIGS. 3A-3M are side, cross-sectional views of various stages in the example process 200. Although the operations discussed below with reference to FIGS. 2 and 3 (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 2 and 3 may be modified in accordance with the present disclosure to fabricate others of microelectronic assembly 100 disclosed herein.

At 205, a dielectric layer (e.g., a layer of the dielectric material 112) is deposited on a substrate, e.g., a first portion of the substrate 107. FIG. 3A illustrates an assembly that includes a first portion of a substrate, e.g., a first portion of the substrate 107. The portion illustrated in FIG. 3A may be referred to as a preliminary substrate. The preliminary substrate includes a carrier 302. The carrier 302 may include any suitable material for providing mechanical stability during manufacturing operations, such as glass, or may include a core (e.g., the core 109) with or without through vias (e.g., the through vias 115 as shown in FIG. 1). In this example, the carrier 302 includes vias formed from a conductive material 306.

The preliminary substrate further includes a dielectric material 304, which may be the dielectric material 112, and patterned conductive material 306. In this example, the dielectric material 304 and conductive material 306 are on either side of the carrier 302. In other examples, the dielectric material 304 and/or conductive material 306 may only be on the upper side of the carrier 302. The patterned conductive material 306 in the dielectric material 304 on the upper side of the carrier 302 may include at least the N-5 and N-4 metal layers shown in FIG. 1. The assembly of FIG. 3A may be manufactured using conventional package substrate manufacturing techniques (e.g., lamination of layers of the dielectric material 304, etc.). A top surface of the dielectric material 304 may be planarized using chemical-mechanical polishing (CMP) or any other suitable process.

FIG. 3B illustrates an assembly after the process 205 of depositing a dielectric layer over the preliminary substrate. The dielectric layer may be deposited using lamination or another suitable method.

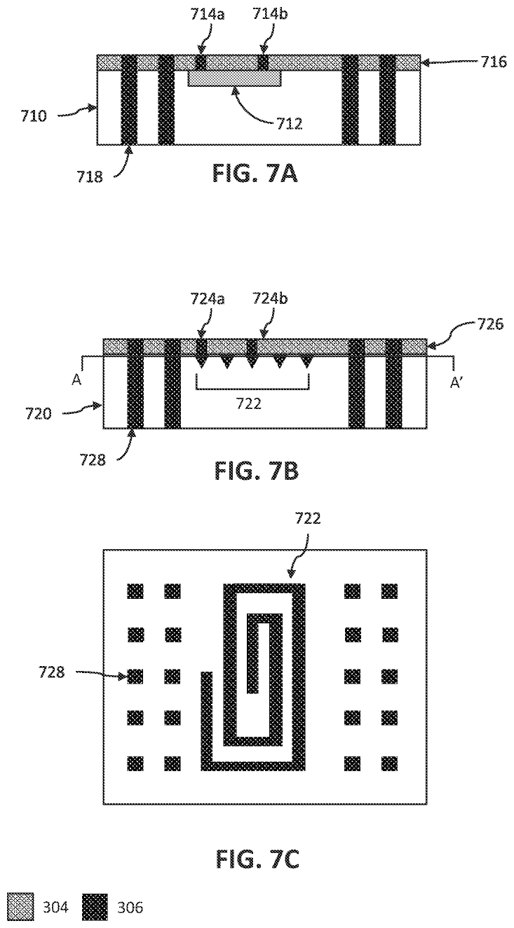

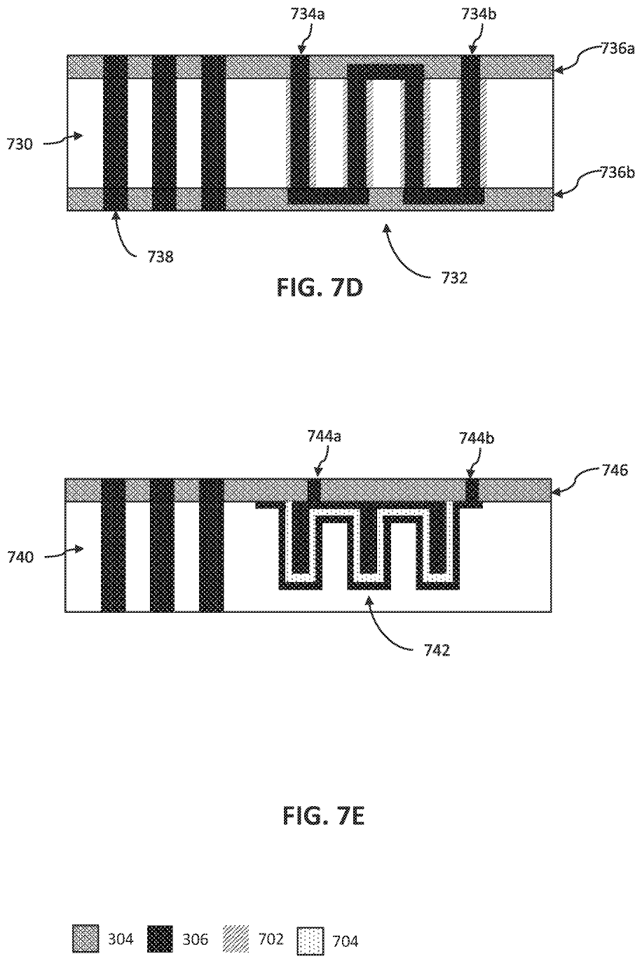

At 210, a glass structure is attached to the substrate. FIG. 3C illustrates an assembly after the process 210 of attaching a glass structure 308. The glass structure 308 may be the glass structure 116, without the vias 117 therein. In some embodiments, the glass structure 308 may include one or more passive components. For example, the glass structure 308 may be any of the structures illustrated in FIGS. 7A-7E. The glass structure 308 includes via openings 322, which may have been previously formed in the glass structure 308 before it is attached to the substrate. As described above, the via openings 322 may be formed using LIDE, photolithography, or another suitable method. The glass structure 308 may be attached to the substrate using a bonding material, such as a bonding film, or without a bonding material.

At 215, via openings in the dielectric material under the glass structure are etched. The glass structure with the via openings acts as a mask for etching via openings in the dielectric material below the glass structure. This results in via openings that are precisely aligned with the glass structure; the via openings may also be referred to as self-aligned via openings, because the via openings are aligned to the layer above them (i.e., the glass structure).

FIG. 3D illustrates an assembly after the process 215 of etching the via openings. As shown in FIG. 3D, the layer 320 of dielectric material 304 is etched away, except for the regions of the layer 320 under the glass structure 308. This results in via openings 324 in the dielectric material 304 below the glass structure 308 and above the uppermost traces in the preliminary substrate (e.g., the N-4 layer). Portions of the traces below the glass structure 308 (and, in particular, portions of the traces below the via openings 322 in the glass structure 308) are exposed as a result of the etching.

At 220, a seed layer is deposited. The seed layer is a suitable material for growing regions of another material, e.g., copper or another conductive material. In general, a seed layer is a thin initial coating of a material (e.g., a metal) that acts as a nucleation site for a subsequent growth process. Various deposition techniques can be used to deposit the seed layer, including, e.g., atomic layer deposition (ALD), chemical vapor deposition (CVD), physical vapor deposition (PVD), etc.

FIG. 3E illustrates an assembly after the process 220 of depositing the seed layer. As shown in FIG. 3E, a layer 326 of the conductive material 306 is deposited over the glass structure 308 and exposed dielectric material 304. The layer 326 extends into the via openings 322 and 324 and over the exposed portions of the traces below the openings 324. The layer 326 further extends across the upper face of the substrate on either side of the glass structure 308.

At 225, a resist is deposited and patterned. For example, a photoresist is deposited over the seed layer 326, e.g., using spin coating. The photoresist is then patterned, which changes a physical property of a portion of the photoresist. For example, a patterned mask may be arranged over the photoresist, and some portions of the photoresist are exposed to patterned actinic radiation through the patterned mask. Some portions of the photoresist (either the exposed portions or the non-exposed portions, depending on the chemistry) can then be removed through a developing process to form openings in the photoresist layer.

FIG. 3F illustrates a resist 310 formed and patterned over the seed layer 326. The resist 310 may have a thickness at least as high as the glass structure 308, or higher than the glass structure 308. FIG. 3F further illustrates that regions have been patterned in the resist 310. For example, regions 328 where vias between the substrate and a die (e.g., the dies 114-2 and 114-3) are to be formed are removed. In addition, a region 330 over the glass structure 308 is removed. Removing the resist 310 in these regions 328 and 330 exposes the seed layer 326 below these regions. The resist 310 may be removed in a developing process, as described above.

At 230, a conductive material is formed in the patterned openings of the resist. For example, copper or another metal may be grown using an electroless deposition or electroplating process. The conductive material is deposited or plated over the seed material.

FIG. 3G illustrates an assembly after the process 230 of forming the conductive material in the patterned openings of the resist. The conductive material 306 has been formed (e.g., by plating or deposition) in the via openings, including the openings 322, 324, 328, and 330, forming conductive vias within the glass structure 308 and next to the glass structure 308. In particular, the conductive material 306 forms vias 334 extending outside the glass structure 308 but in a same layer of the substrate as the glass structure 308. While the vias 334 illustrated in FIG. 3 do not taper, in some embodiments, the vias 334 are tapered, e.g., as shown in FIG. 1. In such embodiments, the openings 328 may have a tapered shape resulting from the etching process.

The conductive material 306 further forms the TGVs 332 that extend through the glass structure 308, from the top face of the glass structure 308 to the bottom face of the glass structure 308. In addition, the conductive material 306 forms the aligned vias 336 below the TGVs 332. The aligned vias 336 are formed in the dielectric material 304 to couple the TGVs 332 to traces below the glass structure 308, and the aligned vias 336 are aligned to the TGVs 332. Furthermore, in this example, a layer 338 of the conductive material 306 is formed over the top of the glass structure 308.

At 235, the resist and the exposed seed layer are removed. For example, the resist is removed through a first chemical process (e.g., a wet etch or a dry etch), and the portions of the seed layer that were under the resist are then removed through a second chemical process (e.g., a wet etch or a dry etch).

FIG. 3H illustrates that exposed portions of the seed layer 326 and the resist 310 have been removed. Portions of the seed layer 326 are still present under the conductive material 306, e.g., under the vias 332, 334, and 336, and the region 338. The removal of the seed layer 326 may thin the vias 334 and the region 338. However, the seed layer 326 is significantly thinner than the height and width of the vias 334, and thinner than the height of the region 338, so after removal of the seed layer 326, the other conductive regions (e.g., the vias 334 and the region 338) remain substantially intact.

At 240, additional dielectric is filled between the vias and glass structure and the assembly is planarized. The deposition of additional dielectric layers may be performed using any of the methods described above. A top surface of the dielectric material 304 and the top surface of the glass structure 308, and in particular, the conductive region 338 formed over the glass structure 308, may be planarized using CMP or any other suitable process.

FIG. 3I illustrates an assembly after the process 240 of depositing additional dielectric and planarizing the assembly. The dielectric material 304 fills regions between the vias 334 and between the vias 334 and the glass structure 308. Furthermore, the conductive region 338 over the glass structure 308 is removed.

At 245, additional metal layers are built over the substrate. In particular, additional layers of dielectric may be formed over the substrate, and additional metal layers formed therein. FIG. 3J illustrates an assembly after the process 245 of depositing additional metal layers, e.g., additional layers of dielectric with conductive vias and conductive traces formed therein. Referring to the layers illustrated in FIG. 1, the layers N-3, N-2, and N-1 have been formed in FIG. 3J. In this example, no conductive vias or traces are formed in the region over the glass structure 308. In other examples, dummy conductive material may be formed in this region.

At 250, a cavity is etched in the dielectric material of the substrate, and in particular, in the at least a portion of the region of the substrate formed over the glass structure 308. The cavity may be formed using any suitable techniques, such as laser patterning techniques or lithography. The cavity may extend to a top surface of the glass structure 308.

FIG. 3K illustrates an assembly after forming a cavity 340 in the dielectric material 304 at the top surface of the assembly of FIG. 3K. In this example, the cavity 340 extends to a top surface of the glass structure 308, including the top surfaces of the TGVs 332 formed in the glass structure 308. In this example, the cavity 340 extends nearly to the edges of the glass structure 308. A small buffer region of dielectric material 342 may remain above the edges of the glass structure 308.

At 255, a bridge die is bonded to the glass structure. A lower face of the bridge die may be bonded to the upper face of the glass structure using direct bonding or hybrid bonding. Direct bonding includes metal-to-metal bonding techniques, e.g., copper-to-copper bonding, or other techniques in which bonding contacts of opposing bonding interfaces are brought into contact first, then subject to heat and compression. Hybrid bonding includes techniques in which bonding dielectric of opposing bonding interfaces, possibly first subjected to prior surface activation, are brought into contact first, then subject to heat and sometimes compression, or techniques in which the bonding contacts and the bonding dielectric, possibly first subjected to prior surface activation, of opposing bonding interfaces are brought into contact substantially simultaneously, and the subject to heat and sometimes compression. Thus, hybrid bonding includes both metal-to-metal bonding at the bonding contacts as well as dielectric-to-dielectric bonding in regions between the contacts. The materials of opposing bonding dielectrics can be homogeneous (i.e., have substantially the same material composition) or non-homogeneous (i.e., have different material compositions).

FIG. 3L illustrates an assembly after bonding a bridge die 312 to the glass structure 308. The bridge die 312 may be the same as the bridge die 114-1 described with respect to FIG. 1. The bridge die 312 includes conductive contacts at its top and bottom faces, and conductive pathways formed therein (e.g., vias between the conductive contacts). The conductive contacts (e.g., the conductive contacts 122) at the lower face of the bridge die 312 are bonded to the TGVs 332 in the glass structure 308. A portion 344 of the cavity 340 remains between the edges of the bridge die 312 and the dielectric material 304, surrounding the bridge die 312; this portion 344 of the cavity may be filled in later with dielectric (e.g., in process 260).

At 260, additional metal layers are built, and dies are attached to the substrate. In particular, additional layers of dielectric may be formed over the substrate (including over the bridge die), and additional metal layers formed therein. Additional dies, such as the dies 114-2 and 114-3 described with respect to FIG. 1, are coupled to the substrate, e.g., using direct bonding or a solder bonding process described with respect to FIG. 1.

FIG. 3M illustrates an assembly after the process 245 of depositing additional metal layers and attaching dies to the substrate. In this example, additional vias and traces are formed over the bridge die 312 and in other regions of the substrate. Two dies 314 are attached to the substrate. The dies 314 are electrically coupled to the bridge die 312, as described with respect to FIG. 1. While FIG. 3M does not specifically illustrate the solder bonding, the dies 314 may be coupled to the substrate via solder bonds, as shown in FIG. 1 and described above.

### Details of TGVs and Self-Aligned Vias Under Glass Patch

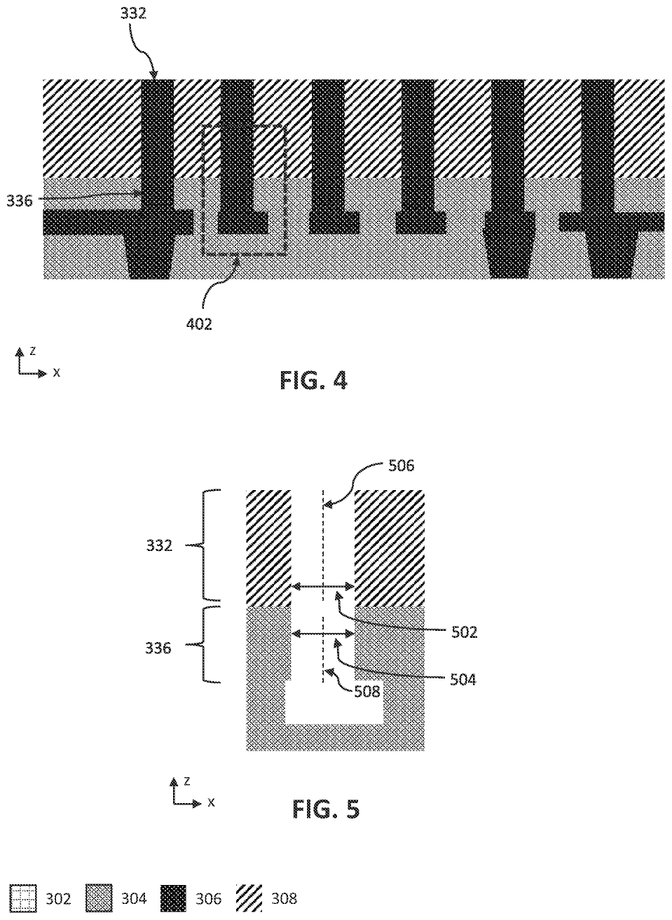

FIG. 4 illustrates a zoomed-in detailed view of the portion 346 of FIG. 3M. FIG. 4 illustrates the TGVs 332 and the aligned vias 336 formed below the TGVs 332. The aligned vias 336 are self-aligned to the TGVs 332.

FIG. 5 is an example zoomed view of the portion 402 of FIG. 4. The shading of the conductive material 306 is removed for ease of illustration; the regions 332 and 336 are filled with the conductive material 306 to form the vias, as described above. FIG. 5 illustrates one TGV 332 and the aligned via 336 formed below the TGV 332. FIG. 5 further includes a width 502 of the TGV 332 and a width 504 of the aligned via 336. The widths 502 and 504 may be generally the same, e.g., the same widths in the x-direction in the orientation shown. For example, the widths 502 and 504 may be within 0.5 microns, 1 micron, 2 microns, 3 microns, 5 microns, or another tolerance. In some embodiments, the TGV 332 may have a slightly smaller width 502 than the width 504 of the aligned via 336, or vice versa, as a result of the processing of etching the aligned via 336. The widths of the TGV 332 and aligned via 336 may also be substantially equal in the y-direction, as may be viewed through a cut perpendicular to the cut illustrated in the figures.

FIG. 5 also includes a center line 506 of the TGV 332 and a center line 508 of the aligned via 336. The center lines 506 and 508 represent a midline of the structures 332 and 336, respectively, in the x-direction. The center lines 506 and 508 are substantially aligned in the x-direction in the orientation shown, and are also substantially aligned in the y-direction, as may be viewed through a cut perpendicular to the cut illustrated in the figures. For example, the center line 506 and the center line 508 may be aligned to within 0.05 microns, 0.1 microns, 0.2 microns, 0.5 microns, 1 micron, or another tolerance.

### Modified Process for Forming Assembly with Glass Patch Under Embedded Bridge

In some embodiments, a layer of material, such as a decomposable polymer, is deposited over the glass patch, prior to cavity formation and bonding of the bridge die. This layer of material may protect the glass structure and TGVs during cavity formation.

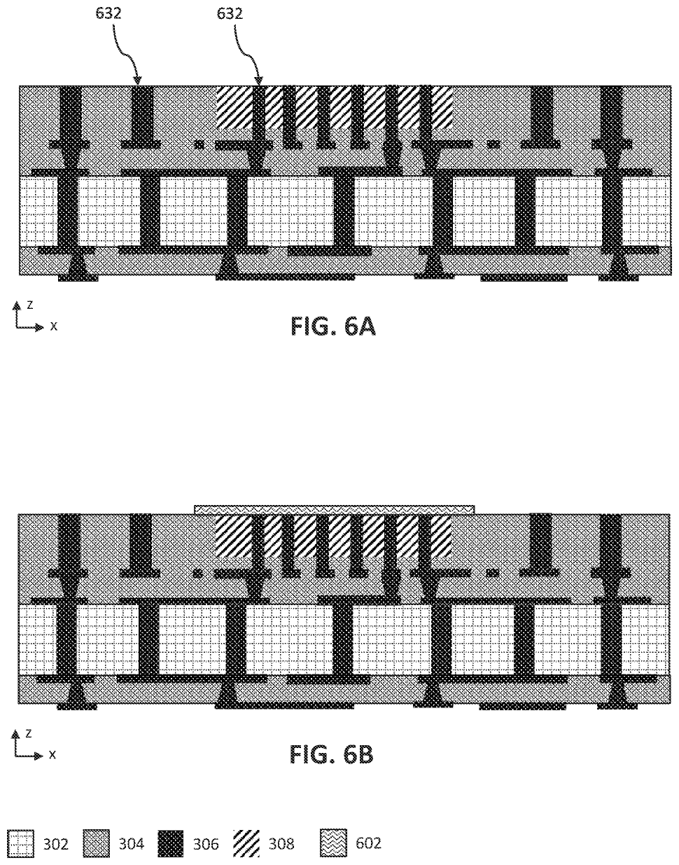

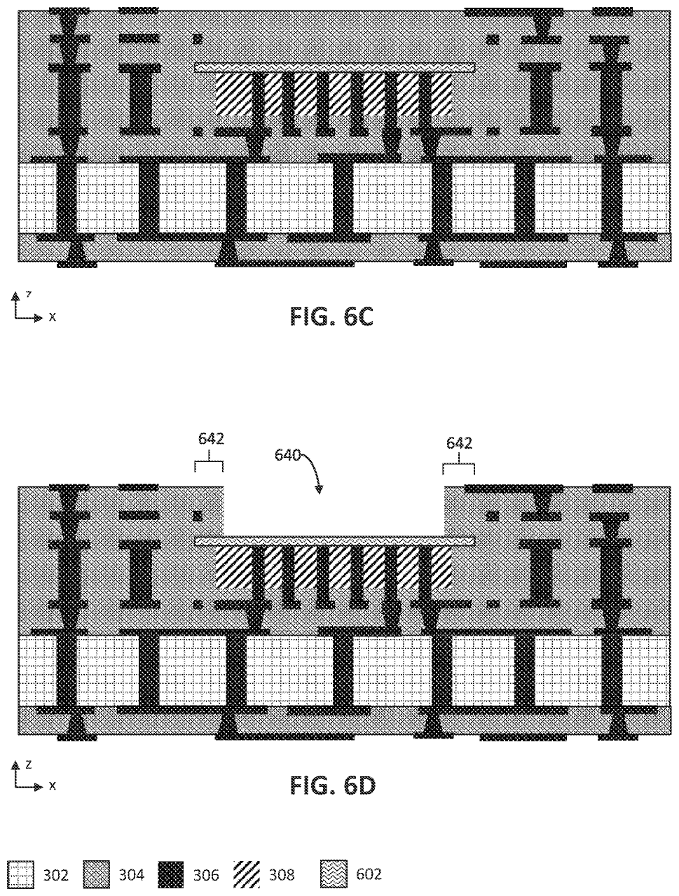

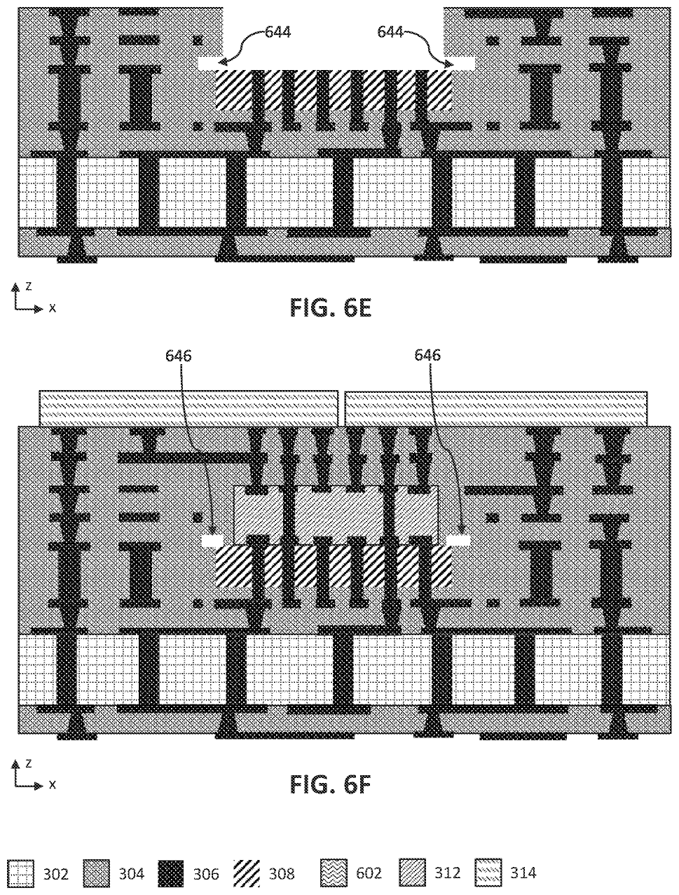

FIGS. 6A-6F are side, cross-sectional views of various stages in another example process for manufacturing a microelectronic assembly, in accordance with various embodiments. FIG. 6. includes several of the same materials and structures as FIG. 3, and the same numbering and patterns used in FIG. 3 are used in FIG. 6.

FIG. 6A illustrates an assembly with a glass structure 308 over a preliminary substrate, the glass structure 308 having TGVs 632 formed therein, dielectric material 304 around the glass structure 308, and vias 634 in the dielectric material 304. FIG. 6A has the same structure as FIG. 3I, described above, and may be formed according to the processes 205-240, described above and illustrated in FIGS. 3A-3I. with vias an assembly after the process 240 of depositing additional dielectric and planarizing the assembly.

FIG. 6B illustrates the assembly of FIG. 6A after a blocking material 602 has been deposited over the glass structure 308. The blocking material 602 covers the glass structure 308 and protects the glass structure 308 during further processing, e.g., during the etching of the cavity over the glass structure 308. The blocking material 602 extends beyond the borders of the glass structure 308, e.g., a surface area of the blocking material 602 in the x-y plane is greater than the surface area of the top of the glass structure 308 in the x-y plane. Said another way, the width of the blocking material 602 (where width is measured in the y-direction in the coordinate system shown) is greater than the width of the glass structure 308, and the length of the blocking material 602 (where length is measured in the x-direction in the coordinate system shown) is greater than the length of the glass structure 308. The blocking material 602 may be titanium, nickel, or another metal that can be selectively etched, so that the conductive material 306 is not removed during etching of the blocking material 602. In some embodiments, the blocking material 602 is a thermally decomposable material that decomposes when heat is applied.

FIG. 6C illustrates the assembly of FIG. 6B after additional metal layers are built over the substrate. As described above with respect to the process 245, additional layers of dielectric may be formed over the substrate, and additional metal layers formed therein. Referring to the layers illustrated in FIG. 1, the layers N-3, N-2, and N-1 have been formed in FIG. 6C. In this example, no conductive vias or traces are formed in the region over the glass structure 308 and blocking material 602. In other examples, dummy conductive material may be formed in this region.

FIG. 6D illustrates the assembly of FIG. 6C after a cavity 640 is etched in the dielectric material of the substrate, and in particular, in the at least a portion of the region of the substrate formed over the glass structure 308. As described with respect to the process 250, the cavity may be formed using any suitable techniques, such as laser patterning techniques or lithography. In this example, the cavity 640 extends to a top surface of the blocking material 602. The cavity 640 extends nearly to the edges of the glass structure 308. A ring of the blocking material 602 remains underneath a layer of the dielectric 304; two portions of the ring are labeled 642.

FIG. 6E illustrates the assembly of FIG. 6D after the removal of the blocking material 602. The blocking material may be removed by a selective etching process, a thermal decomposition process, or another removal process based on the material selected for the blocking material 602. After removal of the blocking material 602, the cavity 640 extends to a top surface of the glass structure 308, including the top surfaces of the TGVs 632 formed in the glass structure 308. In addition, following removal of the blocking material 602, a ring 644 remains around the edge of the glass structure 308. The ring 644 is left vacant by removal of the blocking material 602. The ring 644 is in a layer over the glass structure 308, and at least a portion of the ring 644 is directly over the glass structure 308, while another portion of the ring 644 may be outside the boundary of the glass structure 308.

FIG. 6F illustrates the assembly of FIG. 6E after bonding a bridge die 312 to the glass structure 308, building additional metal layers, and attaching dies to the top of the substrate. These processes may be similar to the processes 255 and 260, described above. After bonding the bridge die 312 over the glass structure 308 and building additional layers on substrate, an air gap 646 remains in the substrate. The air gap 646 is a ring at the location of the ring 644. The air gap 646 is in a layer over the glass structure, and is in the same layer as a portion of the bridge die 312, e.g., adjacent to a lower portion of the bridge die 312. In this example, the dies 314 are bonded to the substrate via direct bonding, rather than the solder bonds illustrated in FIG. 1; alternatively, the dies 314 may be bonded using solder bonds, as described above.

### Example Glass Patches with Passive Devices

As described above, in some embodiments, a glass patch, e.g., the glass structure 116 illustrated in FIG. 1, or the glass structure 308 illustrated in FIGS. 3 and 6, may include one or more passive devices. FIGS. 7A-7E illustrate several example implementations of glass patches including passive devices, in accordance with various embodiments. While the examples above illustrated glass structures having self-aligned vias (e.g., the vias 118) formed underneath and a bridge die bonded to the glass structure using hybrid or direct bonding, in some embodiments, solder bonds are included above and/or below the glass structures illustrated in FIG. 7.

FIG. 7 uses a different pattern (solid white) to illustrate the glass structure, but the same patterns as used in FIGS. 3-6 to illustrate a dielectric material 304 and a conductive material 306. In general, the passive devices illustrated in FIGS. 7A-7E may be fabricated prior to mounting the glass structure in a substrate. If a passive device is arranged at or near a top of the glass structure, the passive device may be blocked (e.g., using a blocking material described with respect to FIG. 6) during additional processing of the substrate (e.g., during cavity formation) to protect the passive device.

FIG. 7A illustrates a cross-section of a glass structure 710 having a passive component 712 embedded in the glass structure. The passive component 712 may be separately fabricated and packaged prior to integration in the glass structure 710. The glass structure 710 includes TGVs 718, similar to the TGVs described above. The passive component 712 may include one or more passive devices of the same or different types, e.g., one or more inductors, one or more capacitors, etc. The passive component package is attached to the glass structure 710, e.g., embedded in a cavity or recess of the glass structure 710. While the passive component 712 in FIG. 7A is illustrated as being in a recess near an upper face of the glass structure 710, in other embodiments, the passive component 712 may be within the glass structure 710, or in a recess along a base or bottom of the glass structure 710. In still other embodiments, the passive component 712 may not be within a recess, but instead be attached to a top or bottom surface of the glass structure 710.

In this example, two contacts 714a and 714b are coupled to the passive component 712, and may be coupled to corresponding contacts on a bridge die. In other embodiments, more or fewer contacts may be included, e.g., based on the number of passive devices included in the passive component 712. The contacts 714a and 714b are in a dielectric layer 716. The dielectric layer 716 may be a layer between the glass structure 116 and the bridge die 114 that is fabricated as part of the substrate 107. Alternatively, the dielectric layer 716 may be part of the glass structure 710, e.g., the dielectric layer 716 may include glass, or a layer that is formed over the glass structure 710 during fabrication of the glass structure 710 and prior to attaching the glass structure 710 to a substrate (e.g., the substrate 107). The TGVs 718 also extend through the dielectric layer 716 (e.g., if the dielectric layer 716 is a glass layer and/or part of the glass structure 710), or are coupled to vias in the dielectric layer 716 (e.g., if the dielectric layer 716 is formed over the glass structure 710 in the substrate 107). While the contacts 714 are both illustrated as extending to an upper surface of the glass structure 710, in other embodiments, one or more contacts may extend downward from the passive component 712, e.g., to receive an input power from a contact in the substrate that is below the glass structure (when it is embedded in the substrate).

FIGS. 7B illustrates a cross-section of a glass structure 720 having conductive material 306 therein that is arranged to form a passive component, and in particular, an inductor 722. FIG. 7C is a cross-section through the plane AA' in FIG. 7B. In this example, the inductor 722 is formed from a coil of conductive material 306 along an upper surface of the glass structure 720. In some embodiments, the inductor 722 has a different shape, or a different type of passive device may be formed in the surface. In other embodiments, multiple passive devices (e.g., multiple inductors) are formed in the glass structure 720. In some embodiments, one or more passive devices are formed along a bottom surface of the glass structure 720.

The inductor 722 may be formed by etching a portion of the glass structure 720 and filling the etched portion with the conductive material 306. In some embodiments, the conductive material 306 may be deposited after the glass structure 720 has been mounted to a substrate (e.g., the substrate 107), e.g., the conductive material 306 forming the inductor 722 may be deposited in the process 230 for filling the TGVs 728. In other embodiments, the conductive material 306 may be deposited in the glass structure 720 before the glass structure 720 is mounted in a substrate; in such embodiments, the conductive material 306 may be protected (e.g., by a mask or blocking material) during further processing of the substrate, as described with respect to FIG. 7A.

In this example, two contacts 724a and 724b are coupled to the inductor 722, and may be coupled to corresponding contacts on a bridge die. The contacts 724a and 724b are in a dielectric layer 726. The arrangement of the contacts 724 and dielectric layer 726 may be similar to the contacts 714 and dielectric layer 716 described with respect to FIG. 7A.

FIG. 7D illustrates a cross-section of a glass structure 730 having conductive material 306 and a magnetic material 702 therein, where the conductive material 306 and magnetic material 702 are arranged to form a passive component, and in particular, an inductor 732. In this example, the inductor 732 includes a conductive material 306 that extends through the glass structure 730 (e.g., in inductor TGVs), and is surrounded in the inductor TGVs by a magnetic material 702, forming a coaxial inductor. The magnetic material 702 may be plated in the inductor TGVs, which are then filled with the conductive material 306. The conductive material 306 may be a different conductive material from the conductive material in the substrate 107.

In this example, an upper dielectric layer 736a, which may be similar to the dielectric layer 716, is along a top of or over top of the glass structure 730, and a lower dielectric layer 736b is along the bottom of or below the base of the glass structure 730. Connections between inductor TGVs may be formed along or within the upper and lower dielectric layers 736. The contacts 734a and 734b are similar to the contacts 714 and 724.

FIG. 7E illustrates a cross-section of a glass structure 740 having conductive material 306 and an insulating material 704 therein, where the conductive material 306 and insulating material 704 are arranged to form a passive component, and in particular, a capacitor 742. The capacitor 742 is a deep trench metal-insulator-metal (MIM) capacitor, where the insulating material 704 is between two layers of the conductive material 306 (e.g., a metal), referred to as plates. In this example, each plate of the capacitor 742 is coupled to a respective contact 744a or 744b, which extend through the dielectric layer 746. The dielectric layer 746 is similar to the dielectric layers 716, 726, and 736 described above.

### EXAMPLE DEVICES

The microelectronic assemblies 100 disclosed herein may be included in any suitable electronic component. FIGS. 8-11 illustrate various examples of apparatuses that may include, or be included in, any of the microelectronic assemblies 100 disclosed herein.

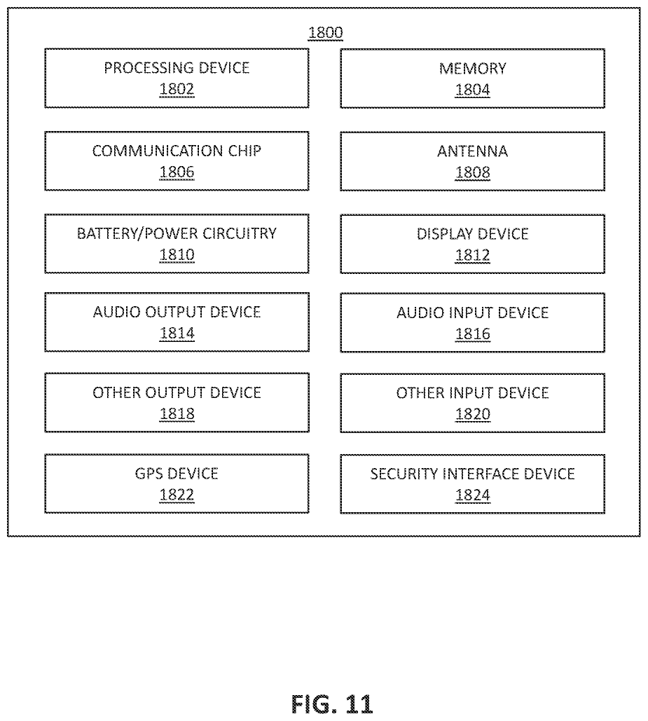

FIG. 8 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 9, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 9 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 8). The IC device 1600 may be formed on a die substrate 1602 (e.g., the wafer 1500 of FIG. 8) and may be included in a die (e.g., the die 1502 of FIG. 8). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 8) or a wafer (e.g., the wafer 1500 of FIG. 8).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a PMOS or a NMOS transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 9. Although a particular number of interconnect layers 1606-1610 is depicted in FIG. 9, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 9. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 9. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 9, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

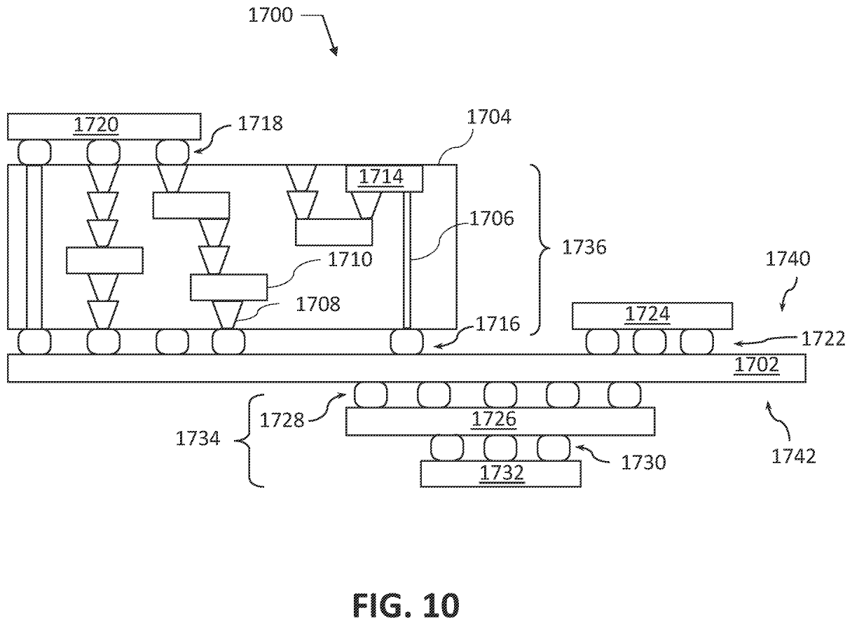

FIG. 10 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8), an IC device (e.g., the IC device 1600 of FIG. 9), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

### SELECT EXAMPLES

The following paragraphs provide various examples of the embodiments disclosed herein.

Example 1 provides an assembly including a substrate; a bridge component in the substrate, the bridge component including a first plurality of conductive contacts at a first face of the bridge component and a second plurality of conductive contacts at a second face of the bridge component, the second face opposite the first face; and a glass structure in the substrate, a face of the glass structure coupled to the second face of the bridge component.

Example 2 provides the assembly of example 1, where the glass structure has a plurality of conductive vias therein, where one of the conductive vias is coupled to one of the second plurality of conductive contacts.

Example 3 provides the assembly of example 2, the substrate including a layer below the glass structure, the layer including a conductive via therein, where the conductive via in the layer of the substrate is aligned with one of the plurality of conductive vias in the glass structure.

Example 4 provides the assembly of example 3, where the conductive via in the glass structure has a first width, the conductive via in the layer of the substrate has a second width, and the first width and the second width are within 2 microns of each other.

Example 5 provides the assembly of example 3 or 4, where a midline of the conductive via in the glass structure is within 0.2 micron of a midline of the conductive via in the layer of the substrate.

Example 6 provides the assembly of any of the preceding examples, where the face of the glass structure is coupled to the second face of the bridge component with direct metal-to-metal bonds.

Example 7 provides the assembly of any of the preceding examples, where the face of the glass structure has a first length, and the second face of the bridge component has a second length, the first length greater than the second length.

Example 8 provides the assembly of example 7, where the face of the glass structure has a first width, the first width extending in a direction perpendicular to the first length, and the second face of the bridge component has a second width, the first width greater than the second width.

Example 9 provides the assembly of example 7, further including an air gap in the substrate, the air gap over the glass structure and next to a lower portion of the bridge component.

Example 10 provides the assembly of any of the preceding examples, where the glass structure includes a glass material surrounding a plurality of through-glass vias, the glass material including at least 23% silicon by weight.

Example 11 provides the assembly of any of the preceding examples, where the glass structure includes a glass material surrounding a plurality of through-glass vias, the glass material including at least 26% oxygen by weight.

Example 12 provides the assembly of any of the preceding examples, where the glass structure includes a glass material surrounding a plurality of through-glass vias, the glass material including at least 23% silicon by weight and at least 26% oxygen by weight.

Example 13 provides the assembly of any of the preceding examples, where the glass structure includes a glass material surrounding a plurality of through-glass vias, the glass material including at least 5% aluminum by weight.

Example 14 provides the assembly of any of the preceding examples, where the glass structure does not include an organic adhesive or an organic material.

Example 15 provides the assembly of any of the preceding examples, where the glass structure includes an embedded passive component.

Example 16 provides the assembly of example 15, where the passive component is an inductor.

Example 17 provides the assembly of example 15, where the passive component is a capacitor.

Example 18 provides a microelectronic assembly, including a substrate; a bridge component in the substrate, the bridge component including a first plurality of conductive contacts at a first face of the bridge component and a second plurality of conductive contacts at a second face of the bridge component, the second face opposite the first face; a glass structure in the substrate, a face of the glass structure coupled to the second face of the bridge component; and a microelectronic component having a first face and an opposing second face, the first face of the microelectronic component is between the second face of the microelectronic component and the substrate, the microelectronic component includes conductive contacts at the first face of the microelectronic component, and a conductive contact of the microelectronic component is conductively coupled to one of the first plurality of conductive contacts at the first face of the bridge component.

Example 19 provides the microelectronic assembly of example 18, where a second conductive contact of the microelectronic component is conductively coupled to a conductive contact of the substrate at the face of the substrate.

Example 20 provides the microelectronic assembly of example 18 or 19, further including a second microelectronic component including a second conductive contact at a face of the second microelectronic component, the second conductive contact conductively coupled to a second one of the first plurality of conductive contacts at the first face of the bridge component.

Example 21 provides an assembly including a glass patch having a first face and a second face opposite the first face; a first die having a first face and a second face, the second face of the first die coupled to the first face of the glass patch; a second die having a face coupled to the first face of the first die; and a third die having a face coupled to the first face of the first die.

Example 22 provides the assembly of example 21, where the first face of the glass patch has a surface area at least as large as a surface area of the second face of the first die.

Example 23 provides the assembly of example 21 or 22, where the glass patch has a through-glass via (TGV) formed therein, the assembly further including a conductive via coupled to the TGV at the second face of the glass patch, the conductive via aligned to the TGV.

Example 24 provides an assembly including a substrate; a bridge component in the substrate, the bridge component including a first plurality of conductive contacts at a first face of the bridge component and a second plurality of conductive contacts at a second face of the bridge component, the second face opposite the first face; a glass structure in the substrate, a face of the glass structure coupled to the second face of the bridge component; and a passive component in the glass structure.

Example 25 provides the assembly of example 24, the passive component including an inductor.

Example 26 provides the assembly of example 24, the inductor including a magnetic material and a conductive material.

Example 27 provides the assembly of any of examples 24 through 26, the passive component coupled to a conductive contact, the conductive contact coupled to one of the second plurality of conductive contacts at the second face of the bridge component.

1. An assembly comprising:
a substrate;
a bridge component in the substrate, the bridge component comprising a first plurality of conductive contacts at a first face of the bridge component and a second plurality of conductive contacts at a second face of the bridge component, the second face opposite the first face; and
a glass structure in the substrate, a face of the glass structure coupled to the second face of the bridge component.

2. The assembly of claim 1, wherein the glass structure has a plurality of conductive vias therein, wherein one of the conductive vias is coupled to one of the second plurality of conductive contacts.

3. The assembly of claim 2, the substrate comprising a layer below the glass structure, the layer comprising a conductive via therein, wherein the conductive via in the layer of the substrate is aligned with one of the plurality of conductive vias in the glass structure.

4. The assembly of claim 3, wherein the conductive via in the glass structure has a first width, the conductive via in the layer of the substrate has a second width, and the first width and the second width are within 2 microns of each other.

5. The assembly of claim 3, wherein a midline of the conductive via in the glass structure is within 0.2 micron of a midline of the conductive via in the layer of the substrate.

6. The assembly of claim 1, wherein the face of the glass structure is coupled to the second face of the bridge component with direct metal-to-metal bonds.

7. The assembly of claim 1, wherein the face of the glass structure has a first length, and the second face of the bridge component has a second length, the first length greater than the second length.

8. The assembly of claim 7, wherein the face of the glass structure has a first width, the first width extending in a direction perpendicular to the first length, and the second face of the bridge component has a second width, the first width greater than the second width.

9. The assembly of claim 7, further comprising an air gap in the substrate, the air gap over the glass structure and next to a lower portion of the bridge component.

10. The assembly of claim 1, wherein the glass structure comprises a glass material surrounding a plurality of through-glass vias, the glass material comprising at least 23% silicon by weight.

11. The assembly of claim 1, wherein the glass structure comprises a glass material surrounding a plurality of through-glass vias, the glass material comprising at least 26% oxygen by weight.

12. The assembly of claim 1, wherein the glass structure comprises an embedded passive component.

13. The assembly of claim 12, wherein the passive component is an inductor or a capacitor.

14. An assembly comprising:
a glass patch having a first face and a second face opposite the first face;
a first die having a first face and a second face, the second face of the first die coupled to the first face of the glass patch;
a second die having a face coupled to the first face of the first die; and
a third die having a face coupled to the first face of the first die.

15. The assembly of claim 14, wherein the first face of the glass patch has a surface area at least as large as a surface area of the second face of the first die.

16. The assembly of claim 14, wherein the glass patch has a through-glass via (TGV) formed therein, the assembly further comprising a conductive via coupled to the TGV at the second face of the glass patch, the conductive via aligned to the TGV.

17. An assembly comprising:
a substrate;
a bridge component in the substrate, the bridge component comprising a first plurality of conductive contacts at a first face of the bridge component and a second plurality of conductive contacts at a second face of the bridge component, the second face opposite the first face;
a glass structure in the substrate, a face of the glass structure coupled to the second face of the bridge component; and
a passive component in the glass structure.

18. The assembly of claim 17, the passive component comprising an inductor.

19. The assembly of claim 17, the inductor comprising a magnetic material and a conductive material.

20. The assembly of claim 17, the passive component coupled to a conductive contact, the conductive contact coupled to one of the second plurality of conductive contacts at the second face of the bridge component.
